(19) United States
(12) Patent Application Publication
(10) Pub. No.: US 2024/0332043 A1
(43) Pub. Date: Oct. 3, 2024

(54) SUBSTRATE PROCESSING APPARATUS

(71) Applicant: Tokyo Electron Limited, Tokyo (JP)

(72) Inventors: Tomoyuki NAGATA, Oshu City (JP); Yoshitaka MIURA, Oshu City (JP)

(21) Appl. No.: 18/616,594

(22) Filed: Mar. 26, 2024

(30) Foreign Application Priority Data
Mar. 31, 2023 (JP) 2023-058775

(51) Int. Cl. H01L 21/67

(52) U.S. Cl. CPC H01L 21/67109

(57) ABSTRACT

A substrate processing apparatus includes a vacuum container configured to accommodate a substrate holder configured to hold a plurality of substrates and having an opening provided in a lower end of the vacuum container, a lid configured to open/close the opening, and a heat-insulating unit configured to insulate a first space below the substrate holder, wherein the heat-insulating unit includes a partition member that forms a second space partitioned from the first space, and the partition member is provided to be rotatable with respect to the lid.

### CROSS-REFERENCE TO RELATED APPLICATION

This application is based upon and claims the benefit of priority from Japanese Patent Application No. 2023-058775, filed on Mar. 31, 2023, the entire contents of which are incorporated herein by reference.

### TECHNICAL FIELD

The present disclosure relates to a substrate processing apparatus.

### BACKGROUND

There is known a substrate processing apparatus in which a substrate holder that holds a plurality of substrates arranged in multiple stages is accommodated in a reaction container having a lower opening, and heat treatment is performed on the plurality of substrates with the lower opening closed by a lid (see, for example, Patent Document 1). In Patent Document 1, a cover part that covers the lid is provided, and a heat-insulating material is installed in a space covered by the cover part.

### PRIOR ART DOCUMENT

### Patent Document

Patent Document 1: Japanese Patent No. 6736755

### SUMMARY

According to an embodiment of the present disclosure, a substrate processing apparatus includes a vacuum container configured to accommodate a substrate holder configured to hold a plurality of substrates and having an opening provided in a lower end of the vacuum container, a lid configured to open/close the opening, and a heat-insulating unit configured to insulate a first space below the substrate holder, wherein the heat-insulating unit includes a partition member that forms a second space partitioned from the first space, and the partition member is provided to be rotatable with respect to the lid.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating a substrate processing apparatus according to a first embodiment.

FIG. 2 is a cross-sectional view illustrating a substrate processing apparatus according to a second embodiment.

FIG. 3 is a cross-sectional view illustrating a substrate processing apparatus according to a third embodiment.

FIG. 4 is a cross-sectional view illustrating a substrate processing apparatus according to a fourth embodiment.

FIG. 5 is a cross-sectional view illustrating a substrate processing apparatus according to a fifth embodiment.

### DETAILED DESCRIPTION

Hereinafter, non-limiting exemplary embodiments of the present disclosure will be described with reference to the accompanying drawings. In all of the accompanying drawings, the same or corresponding members or components will be denoted by the same or corresponding reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

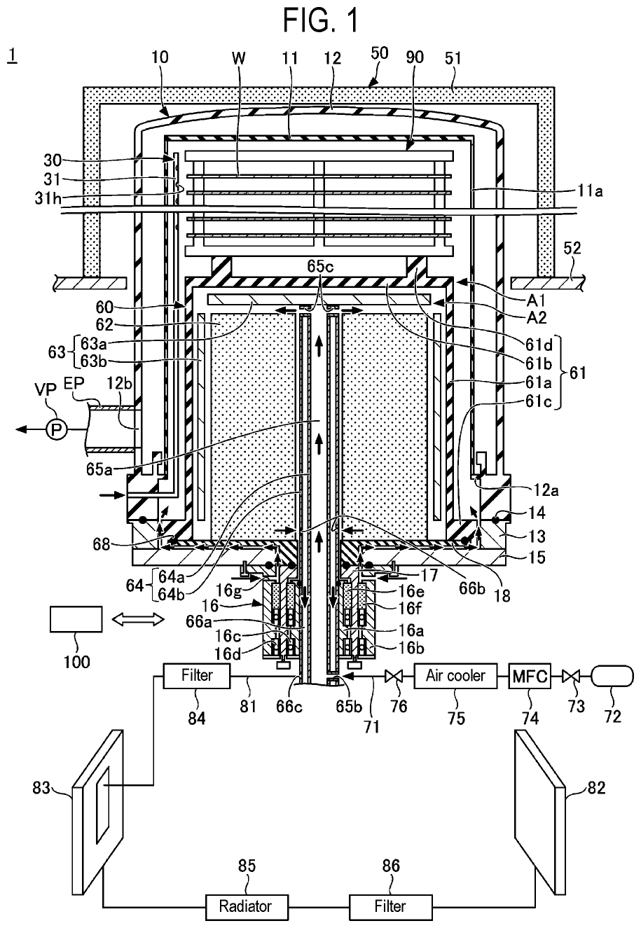

A substrate processing apparatus 1 according to a first embodiment will be described with reference to FIG. 1. FIG. 1 is a cross-sectional view illustrating the substrate processing apparatus 1 according to the first embodiment.

The substrate processing apparatus 1 is a batch-type heat treatment apparatus that performs heat treatment on a plurality of substrates W at once. The substrates W are, for example, semiconductor wafers. The substrate processing apparatus 1 includes a processing container 10, a gas supplier 30, a heating part 50, a heat-insulating unit 60, a substrate holder 90, and a controller 100.

The processing container 10 is a vacuum container whose interior can be depressurized. The processing container 10 accommodates substrates W therein. The processing container 10 includes an inner tube 11, an outer tube 12, and a flange member 13.

Each of the inner tube 11 and the outer tube 12 has a cylindrical shape with a ceiling and an open lower end. The outer tube 12 covers the outside of the inner tube 11. The inner tube 11 and the outer tube 12 are coaxially arranged to have a double tube structure. The inner tube 11 and the outer tube 12 are made of, for example, quartz.

An opening 11a is provided in a sidewall of the inner tube 11. The opening 11a has a rectangular shape extending in a vertical direction. The opening 11a extends, for example, from a position higher than an upper end of the substrate holder 90 to a position lower than a lower end of the substrate holder 90. The opening 11a is provided, for example, at a position facing a gas injector 31. The opening 11a exhausts gas inside the inner tube 11.

The flange member 13 supports the lower end of the outer tube 12. The flange member 13 has a ring shape. The flange member 13 is made of, for example, stainless steel. A sealing member 14 such as an O-ring is provided between a lower surface of the outer tube 12 and an upper surface of the flange member 13. In this case, a gap between the lower surface of the outer tube 12 and the upper surface of the flange member 13 is hermetically sealed. A ring-shaped support 12a is provided on a lower inner wall of the outer tube 12. The support 12a supports the lower end of the inner tube 11. A gas outlet 12b is provided on the sidewall of the outer tube 12 above the support 12a. An exhaust pipe EP is connected to the gas outlet 12b. The exhaust pipe EP is provided with a pressure regulating valve (not illustrated) and a vacuum pump VP. The vacuum pump VP evacuates the interior of the processing container 10 via the exhaust pipe EP. A lid 15 is installed to an opening at a lower end of the processing container 10.

The lid 15 hermetically closes the opening at the lower end of the processing container 10. The lid 15 is made of, for example, metal such as stainless steel. A rotary shaft 17 is provided to pass through the center of the lid 15 via a magnetic fluid seal 16.

The magnetic fluid seal 16 includes an inner fixed shaft 16a, an outer fixed shaft 16b, bearings 16c and 16d, and magnetic fluids 16e and 16f.

The inner fixed shaft 16a is provided inward of the rotary shaft 17. The outer fixed shaft 16b is provided outward of the rotary shaft 17. The outer fixed shaft 16b is fixed to the lower surface of the lid 15. A coolant flow path may be provided inside the outer fixed shaft 16b. The inner fixed shaft 16a and the outer fixed shaft 16b are arranged coaxially with the rotary shaft 17.

The bearing 16c and the magnetic fluid 16e are provided between the inner fixed shaft 16a and the rotary shaft 17. The bearing 16c rotatably supports the rotary shaft 17 with respect to the inner fixed shaft 16a. The magnetic fluid 16e hermetically seals a gap between the inner fixed shaft 16a and the rotary shaft 17.

The bearing 16d and the magnetic fluid 16f are provided between the outer fixed shaft 16b and the rotary shaft 17. The bearing 16d rotatably supports the rotary shaft 17 with respect to the outer fixed shaft 16b. The magnetic fluid 16f hermetically seals a gap between the outer fixed shaft 16b and the rotary shaft 17.

A purge gas inlet 16g is provided in the outer fixed shaft 16b. A purge gas source (not illustrated) is connected to the purge gas inlet 16g via a purge gas supply pipe (not illustrated). A purge gas from the purge gas source is introduced between the outer fixed shaft 16b and the rotary shaft 17 from the purge gas inlet 16g, sequentially passes through a gap between the lid 15 and the rotary table 18 and a gap between the flange member 13 and a partition member 61, and flows into an outer peripheral portion of a first space A1. In this case, the purge gas is difficult to flow into the center of the first space A1, which suppresses dilution of the processing gas by the purge gas in the vicinity of the substrates W. This improves the in-plane uniformity and inter-plane uniformity of the heat treatment. The purge gas prevents the flange member 13, the lid 15, the outer fixed shaft 16b, the rotary shaft 17, the rotary table 18, and the like from being exposed to the processing gas such as a corrosive gas.

The rotary shaft 17 is sandwiched between the inner fixed shaft 16a and the outer fixed shaft 16b. The rotary shaft 17 is rotatable with respect to the inner fixed shaft 16a via the bearing 16c and the magnetic fluid 16e. The rotary shaft 17 is rotatable with respect to the outer fixed shaft 16b via the bearing 16d and the magnetic fluid 16f. A lower portion of the rotary shaft 17 is rotatably supported by an arm (not illustrated) of a lifting mechanism configured with a boat elevator. The rotary shaft 17 moves up and down as the arm moves up and down. The rotary table 18 is fixed to an upper end of the rotary shaft 17.

The rotary table 18 rotates integrally with the rotary shaft 17. The rotary table 18 is rotatable with respect to the lid 15. The rotary table 18 is made of, for example, quartz. A coolant flow path may be provided inside the rotary table 18.

The gas supplier 30 includes the gas injector 31. The gas injector 31 extends vertically along an inner wall of the inner tube 11. The gas injector 31 is bent into an L-shape at the lower portion of the inner tube 11 and extends to the outside of the processing container 10 via the outer tube 12. The gas injector 31 is made of, for example, quartz. An end portion of the gas injector 31 outside the processing container 10 is connected to a gas supply pipe (not illustrated). A gas source (not illustrated) for the processing gas is connected to the gas supply pipe. The gas injector 31 has a plurality of gas ejection holes 31h. The plurality of gas ejection holes 31h are provided at positions extending in the vertical direction along the inner wall of the inner tube 11. The plurality of gas ejection holes 31h are provided at predetermined intervals in the vertical direction. The processing gas from the gas source flows into the gas injector 31 from the gas supply pipe and is ejected into the inner tube 11 from each gas ejection hole 31h.

The gas supplier 30 may mix a plurality of processing gases and eject the mixed processing gas from a single gas injector. In addition to the gas injector 31, the gas supplier 30 may further include a gas injector configured to eject another processing gas.

The heating part 50 includes a chamber heater 51. The chamber heater 51 has a roofed cylindrical shape that surrounds the processing container 10 on the outside of the processing container 10 in the radial direction and covers the ceiling of the processing container 10. The chamber heater 51 is fixed to a base plate 52. The chamber heater 51 heats each substrate W accommodated in the processing container 10 by heating a lateral periphery and the ceiling of the processing container 10.

The heat-insulating unit 60 includes the partition member 61, a heat-insulating material 62, a heater 63, and a fixed shaft 64.

The partition member 61 is installed on the rotary table 18. The partition member 61 forms a second space A2 partitioned from the first space A1. The first space A1 is a space below the substrate holder 90 in the interior of the processing container 10. The first space A1 is switched between an atmospheric environment and a vacuum atmosphere. The second space A2 is an environment outside the processing container 10. The partition member 61 is made of, for example, quartz. The partition member 61 has a roofed cylindrical shape. In this case, since the shape of the partition member 61 is simple, the volume of quartz forming the partition member 61 may be reduced. This makes it possible to reduce a heat capacity of the partition member 61 and shorten the time required to raise and lower a temperature of the second space A2.

The partition member 61 includes a sidewall portion 61a, a ceiling wall portion 61b, a flange portion 61c, and a support 61d. For example, the sidewall portion 61a, the ceiling wall portion 61b, the flange portion 61c, and the support 61d may be formed integrally with each other. The sidewall portion 61a, the ceiling wall portion 61b, the flange portion 61c, and the support 61d may be formed separately from each other.

The sidewall portion 61a has a cylindrical shape. An outer diameter of the sidewall portion 61a is smaller than an inner diameter of the inner tube 11. A lower end of the sidewall portion 61a is installed on the rotary table 18.

The ceiling wall portion 61b closes an upper opening of the sidewall portion 61a. The ceiling wall portion 61b has a disk shape. The ceiling wall portion 61b forms the second space A2 partitioned from the first space A1, together with the rotary table 18 and the sidewall portion 61a.

The flange portion 61c extends from the bottom of the sidewall portion 61a outward of the sidewall portion 61a in the radial direction. A sealing member 68 such as an O-ring is provided between a lower surface of the flange portion 61c and the upper surface of the rotary table 18. In this case, a gap between the lower surface of the flange portion 61c and the upper surface of the rotary table 18 is hermetically sealed.

The support 61d is provided on the ceiling wall portion 61b. The support 61d protrudes upward from an upper surface of the ceiling wall portion 61b. The support 61d has a ring shape. The support 61d supports the substrate holder 90.

The heat-insulating material 62 is provided in the second space A2. The heat-insulating material 62 is installed on, for example, the rotary table 18. The heat-insulating material 62 may be provided to be spaced apart from the upper surface of the rotary table 18. The heat-insulating material 62 suppresses dissipation of heat from the lower opening of the processing container 10. The heat-insulating material 62 has a structure in which, for example, a fiber-based heat-insulating material is molded into a cylindrical shape. The heat-insulating material 62 may have a structure in which heat-insulating plates made of quartz, silicon carbide, or the like are stacked horizontally at intervals in the vertical direction.

The heater 63 includes a ceiling heater 63a and a sidewall heater 63b. The heater 63 may further include an additional heater. The additional heater is, for example, an injector heater configured to heat the gas injector 31.

The ceiling heater 63a is provided between the ceiling wall portion 61b and the heat-insulating material 62. By providing the ceiling heater 63a, a vertical soaking field in the interior of the processing container 10 is improved. The ceiling heater 63a has, for example, a disk shape. The ceiling heater 63a may be, for example, a carbon-based heater. This makes it possible to improve temperature increase/decrease characteristics and shorten a temperature recovery time. The ceiling heater 63a may be a heater other than the carbon-based heater. Since the second space A2 is a space partitioned from the first space A1, an inexpensive heater such as a sheath heater or a Kanthal wire heater may be used. This makes it possible to significantly reduce costs compared to the carbon-based heater.

The sidewall heater 63b is provided between the sidewall portion 61a and the heat-insulating material 62. The sidewall heater 63b heats the sidewall portion 61a. This makes it possible to suppress by-products from adhering to the surface of the sidewall portion 61a. The sidewall heater 63b has, for example, a cylindrical shape. The sidewall heater 63b may be, for example, a sheath heater. In this case, since far infrared rays are emitted, the sidewall portion 61a formed of quartz is likely to be heated.

The fixed shaft 64 is fixed inward of the inner fixed shaft 16a. The fixed shaft 64 extends vertically via the lid 15. The fixed shaft 64 passes through the rotary shaft 17, the rotary table 18, and the heat-insulating material 62, and the upper end of the fixed shaft 64 is fixed to the lower surface of the ceiling heater 63a. The upper end of the fixed shaft 64 is located in the second space A2 rather than passing through the ceiling wall portion 61b. The fixed shaft 64 includes an inner shaft 64a and an outer shaft 64b. The outer shaft 64b is provided outward of the inner shaft 64a in the radial direction. The inner shaft 64a and the outer shaft 64b are coaxially arranged to have a double tube structure.

The fixed shaft 64 is provided with a supply passage 65a, a supply port 65b, an ejection port 65c, an exhaust passage 66a, a suction port 66b, and an exhaust port 66c.

The supply passage 65a is provided inside the inner shaft 64a. The supply port 65b is open in the inner shaft 64a and the outer shaft 64b so that the supply pipe 71 and the supply passage 65a are in communication with each other. The supply port 65b is provided below, for example, a lower end of the magnetic fluid seal 16. The ejection port 65c is open in the inner shaft 64a and the outer shaft 64b so that the supply passage 65a and the second space A2 are in communication with each other. The ejection port 65c is provided above the supply port 65b. The ejection port 65c is provided above, for example, the upper end of the heat-insulating material 62. With this configuration, a temperature-regulating fluid may be supplied near the substrate holder 90. This makes it easy to raise and lower the temperature of the substrates W held by the substrate holder 90.

The supply pipe 71 is connected to the supply port 65b. The supply pipe 71 is provided with a source 72, a valve 73, a flow rate controller 74, a temperature regulator 75, and a valve 76 in that order from the upstream side. The source 72 is a source of the temperature-regulating fluid. The temperature-regulating fluid is, for example, a coolant such as air or nitrogen. The temperature-regulating fluid may be a heating medium. The valve 73 opens/closes a flow path within the supply pipe 71. The flow rate controller 74 controls a flow rate of the temperature-regulating fluid flowing through the supply pipe 71. The flow rate controller 74 is, for example, a mass flow controller (MFC). The temperature regulator 75 regulates a temperature of the temperature-regulating fluid flowing through the supply pipe 71. The temperature regulator 75 includes, for example, an air cooler. The temperature regulator 75 may include a refrigerator. The valve 76 opens/closes the flow path within supply pipe 71. The temperature-regulating fluid from the source 72 flows from the supply pipe 71 into the supply passage 65a via the supply port 65b, flows upward from a lower portion of the supply passage 65a, and is ejected into the second space A2 from the ejection port 65c.

A power cable configured to supply power to the ceiling heater 63a and the sidewall heater 63b may be inserted through the supply passage 65a. A signal cable configured to control operations of the ceiling heater 63a and the sidewall heater 63b may be inserted through the supply passage 65a.

The exhaust passage 66a is provided between the inner shaft 64a and the outer shaft 64b. The suction port 66b is open in the outer shaft 64b so that the second space A2 and the exhaust passage 66a are in communication with each other. The suction port 66b is provided below, for example, the ejection port 65c. The exhaust port 66c is open in the outer shaft 64b so that the exhaust passage 66a and the exhaust pipe 81 are in communication with each other. The exhaust port 66c is provided below the suction port 66b. The exhaust port 66c is provided, for example, at the same height as the supply port 65b.

The exhaust pipe 81 is connected to the exhaust port 66c. One end of the exhaust pipe 81 is connected to the exhaust port 66c, and the other end thereof is located near the exhaust duct 83 in a loading chamber. The other end of the exhaust pipe 81 may be directly connected to the exhaust duct 83.

The loading chamber is located below the processing container 10. A fan filter unit (FFU) 82 and the exhaust duct 83 are provided in the loading chamber. The fan filter unit 82 supplies a clean gas to the loading chamber. The exhaust duct 83 is arranged to face the fan filter unit 82. The exhaust duct 83 suctions the clean gas supplied to the loading chamber. This maintains the loading chamber in a clean atmosphere. In the loading chamber, substrates W to be subjected to the heat treatment are loaded into the substrate holder 90. In the loading chamber, processed substrates W are unloaded from the substrate holder 90.

A filter 84 is provided in the exhaust pipe 81. The filter 84 removes impurities contained in the temperature-regulating fluid. This makes it possible to prevent the impurities from being introduced into the loading chamber from the second space A2. The impurities may include particles generated when a component provided in the second space A2 is heated and thermally expanded.

A downstream side of the exhaust duct 83 is connected to, for example, the fan filter unit 82. With this configuration, the clean gas may be used in a circulation manner. A heat exchanger 85 and a filter 86 are provided between the exhaust duct 83 and the fan filter unit 82. The heat exchanger 85 is, for example, a radiator, and cools down the clean gas and the temperature-regulating fluid exhausted from the exhaust duct 83. The filter 86 removes impurities contained in the clean gas and the temperature-regulating fluid. The temperature-regulating fluid in the second space A2 flows into the exhaust passage 66a via the suction port 66b, flows downward from an upper portion of the exhaust passage 66a, and is exhausted from the exhaust port 66c to the exhaust pipe 81.

The substrate holder 90 is provided on the partition member 61. The substrate holder 90 is supported by the support 61d. The substrate holder 90 holds a plurality of (for example, 25 to 200) substrates W which are arranged horizontally in multiple stages in the vertical direction. The substrate holder 90 is made of, for example, quartz or silicon carbide. The substrate holder 90 moves up and down integrally with the lid 15, the rotary shaft 17, the rotary table 18, and the partition member 61 as the arm moves up and down. Thus, the substrate holder 90 is inserted into and removed from the processing container 10.

The controller 100 controls, for example, an operation of each part of the substrate processing apparatus 1. The controller 100 may be, for example, a computer. In addition, a computer program for executing the operation of each part of the substrate processing apparatus 1 is stored in a non-transitory computer-readable storage medium. The storage medium may be, for example, a flexible disk, a compact disk, a hard disk, a flash memory, a DVD, or the like.

As described above, the substrate processing apparatus 1 includes the heat-insulating unit 60 that insulates the first space A1 in the processing container 10 located below the substrate holder 90. The heat-insulating unit 60 includes the partition member 61 that forms the second space A2 partitioned from the first space A1. The partition member 61 is provided to be rotatable with respect to the lid 15. With this configuration, by installing the substrate holder 90 on the partition member 61, it is possible to rotate the substrate holder 90 with respect to the lid 15. Therefore, there is no need for a rotary shaft that vertically penetrates the center of the partition member 61 to rotatably support the substrate holder 90. This makes it possible to increase an area for arranging the heat-insulating material 62 within the partition member 61 in a plan view. Thus, a height of the partition member 61 is reduced, which makes it possible to increase an internal volume of the processing container 10 capable of accommodating the substrate holder 90. As a result, it is possible to provide the substrate holder 90 capable of holding more substrates W than those used in the related art, thereby increasing the number of substrates W capable of being heat-treated at once. That is, productivity is improved. In addition, it is possible to provide the substrate holder 90 with a larger pitch between the substrates W than that in the related art. This makes it easier for the processing gas to flow into the surface of each substrate W, thereby improving the in-plane uniformity of heat treatment.

In addition, in the substrate processing apparatus 1, since there is no need to provide a rotary shaft at the center of the partition member 61, the internal volume of the processing container 10 may be reduced. This improves a replacement efficiency of the processing gas supplied into the processing container 10, thereby improving the in-plane uniformity of heat treatment. Further, a surface area of the partition member 61 may be reduced. This reduces the amount of by-products that adhere to the surface of the partition member 61, which makes it possible to suppress the generation of the particles caused by the by-products, reduce degassing from the by-products, and shorten a cleaning time required to remove the by-products. In addition, it is possible to reduce the consumption of the purge gas.

In addition, the substrate processing apparatus 1 includes the rotary shaft 17 provided with the supply port 65b through which the temperature-regulating fluid is supplied to the second space A2 and the exhaust port 66c through which the temperature-regulating fluid is exhausted from the second space A2. With this configuration, it is possible to exhaust the coolant, which has been heated in the second space A2, from the exhaust port 66c, while continuously supplying the coolant from the supply port 65b to the second space A2. This shortens the time required to cool down the heat-insulating unit 60. As a result, it is possible to shorten a waiting time until the processed substrates W are cooled down to a temperature at which the unloading of the substrates is allowable. In addition, it is possible to exhaust the heat medium, which has been cooled in the second space A2, from the exhaust port 66c, while continuously supplying the heat medium from the supply port 65b to the second space A2. This shortens the time required to raise the temperature of the heat-insulating unit 60. Thus, it is possible to shorten a waiting time until the temperature of the substrate W to be heat-treated is raised to a sufficient heat-treatment temperature. As described above, according to the substrate processing apparatus 1, it is possible to shorten the time required for raising and lowering the temperature of the heat-insulating unit 60, which improves productivity. Further, the temperature-regulating fluid in the second space A2 is not discharged into the first space A1. This prevents dilution of the processing gas by the temperature-regulating fluid, and thus improves the in-plane uniformity and inter-plane uniformity of the heat treatment.

In addition, a space for providing the rotary shaft, which penetrates the partition member 61 in the vertical direction, is not required. This suppresses the processing gas from flowing around the rotary shaft 17.

Further, in the substrate processing apparatus 1, the second space A2 is partitioned from the first space A1 by the heat-insulating unit 60. With this configuration, it is possible to cool down the second space A2 by supplying the coolant into the second space A2 during the execution of a step of returning the first space A1 from a processing pressure to the atmospheric environment or a step of unloading the substrate holder 90 from the interior of the processing container 10. This reduces downtime.

In addition, in the substrate processing apparatus 1, one end of the exhaust pipe 81 is connected to the exhaust port 66c, and the other end of the exhaust pipe 81 is located near the exhaust duct 83 in the loading chamber. In this case, the temperature-regulating fluid in the second space A2 is discharged near the exhaust duct 83. Therefore, it is possible to quickly recover, by the exhaust duct 83, the coolant which has been heated by the chamber heater 51, the ceiling heater 63a, the sidewall heater 63b, and the like in the second space A2. This makes it possible to suppress the interior of the loading chamber from being heated. As a result, it is possible to prevent the internal temperature of the loading chamber from exceeding heat-resistant temperatures of resin components or electrical components provided in the loading chamber.

### Second Embodiment

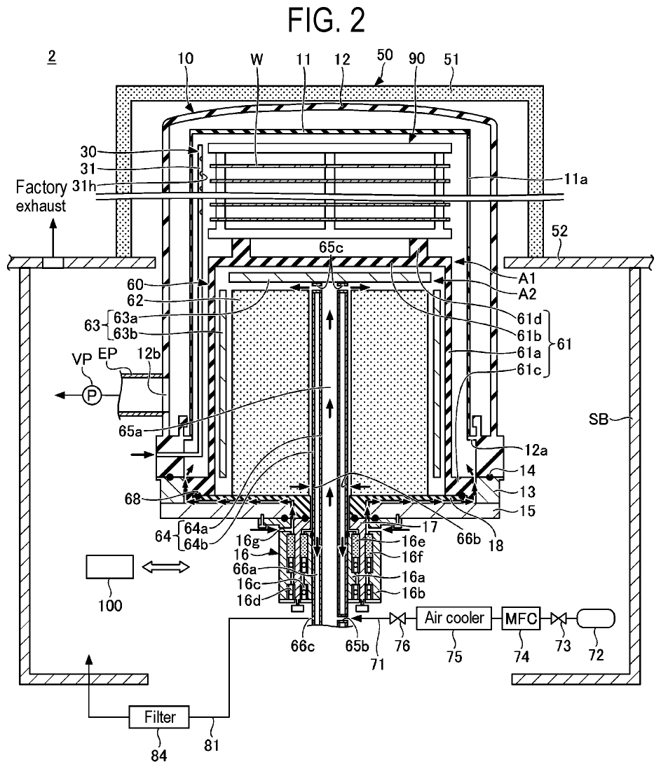

A substrate processing apparatus 2 according to a second embodiment will be described with reference to FIG. 2. FIG. 2 is a cross-sectional view illustrating the substrate processing apparatus 2 according to the second embodiment.

The substrate processing apparatus 2 differs in main configuration from the substrate processing apparatus 1 in that the other end of the exhaust pipe 81 is located inside a scavenger SB. Other configurations are the same as those of the substrate processing apparatus 1. Hereinafter, descriptions will be given focusing on the configurations different from the substrate processing apparatus 1.

One end of the exhaust pipe 81 is connected to the exhaust port 66c, and the other end thereof is located inside the scavenger SB. The scavenger SB is installed on base plate 52. The base plate 52 constitutes the ceiling of the loading chamber. The scavenger SB is provided around the lower opening of the processing container 10. An exhaust passage (not illustrated) for exhausting an internal atmosphere of the scavenger SB is connected to the base plate 52 to prevent exhaust heat in the processing container 10 from flowing into the loading chamber. The exhaust passage is connected to, for example, a factory exhaust system. The exhaust passage may be connected to the scavenger SB.

With the substrate processing apparatus 2 described above, the same effects as those in the substrate processing apparatus 1 are achieved. In particular, in the substrate processing apparatus 2, one end of the exhaust pipe 81 is connected to the exhaust port 66c, and the other end of the exhaust pipe 81 is located inside the scavenger SB. With this configuration, the temperature-regulating fluid in the second space A2 is discharged to the factory exhaust system via the exhaust passage connected to the scavenger SB. This makes it possible to suppress the coolant, which has been heated by the chamber heater 51, the ceiling heater 63a, the sidewall heater 63b, and the like in the second space A2, from flowing into the loading chamber. Thus, it is possible to suppress the interior of the loading chamber from being heated. As a result, it is possible to prevent the internal temperature of the loading chamber from exceeding heat-resistant temperatures of resin components or electrical components provided in the loading chamber.

### Third Embodiment

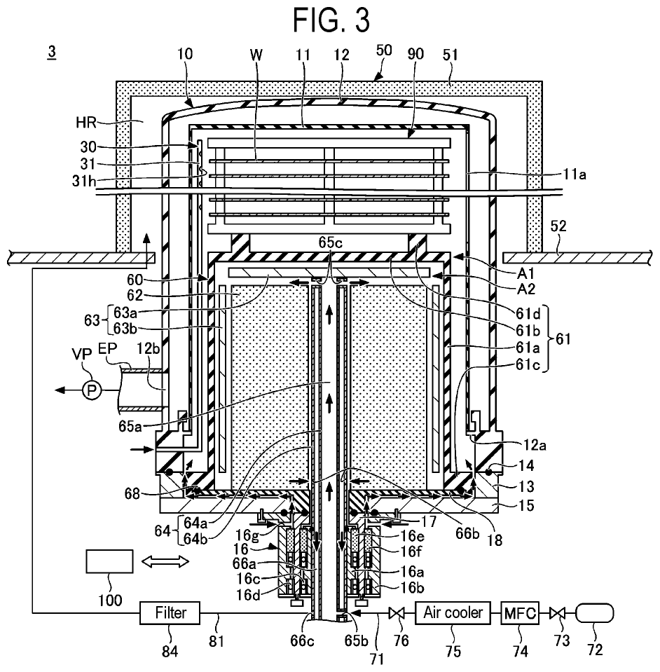

A substrate processing apparatus 3 according to a third embodiment will be described with reference to FIG. 3. FIG. 3 is a cross-sectional view illustrating the substrate processing apparatus 3 according to the third embodiment.

The substrate processing apparatus 3 differs in main configuration from the substrate processing apparatus 1 in that the other end of the exhaust pipe 81 is located inside a heater chamber HR. Other configurations are the same as those of the substrate processing apparatus 1. Hereinafter, descriptions will be given focusing on the configurations different from those of the substrate processing apparatus 1.

One end of the exhaust pipe 81 is connected to the exhaust port 66c, and the other end thereof is located inside the heater chamber HR. The heater chamber HR is a space defined by the outer tube 12, the chamber heater 51, and the base plate 52. The heater chamber HR is located above the loading chamber and between the outer tube 12 and the chamber heater 51. An exhaust passage (not illustrated) for exhausting the internal atmosphere is connected to the heater chamber HR. The exhaust passage is connected to, for example, the factory exhaust system.

With the substrate processing apparatus 3 described above, the same effects as those in the substrate processing apparatus 1 are achieved. In particular, in the substrate processing apparatus 3, one end of the exhaust pipe 81 is connected to the exhaust port 66c, and the other end of the exhaust pipe 81 is located inside the heater chamber HR. In this case, the temperature-regulating fluid in the second space A2 is discharged to the factory exhaust system via the exhaust passage connected to the heater chamber HR. With this configuration, it is possible to suppress the coolant, which has been heated by the chamber heater 51, the ceiling heater 63a, the sidewall heater 63b, and the like in the second space A2, from flowing into the loading chamber. This suppresses the interior of the loading chamber from being heated. As a result, it is possible to prevent the internal temperature of the loading chamber from exceeding the heat-resistant temperatures of resin components or electrical components provided in the loading chamber.

### Fourth Embodiment

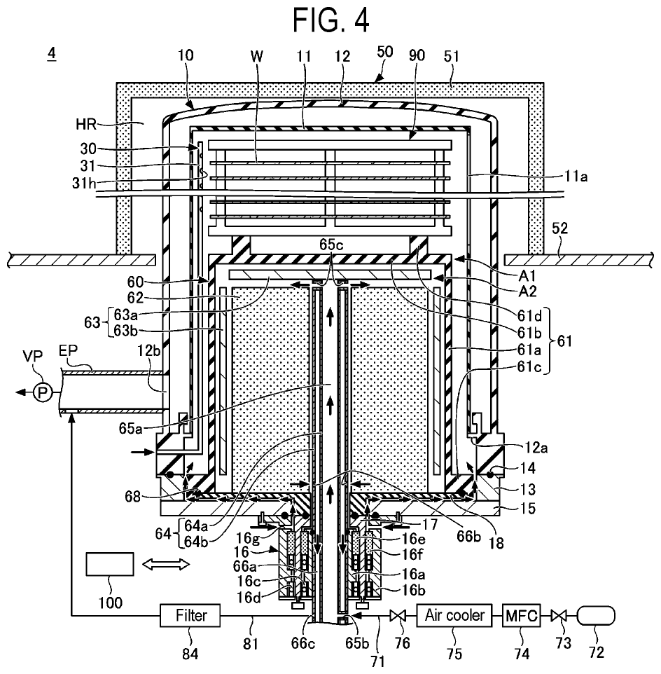

A substrate processing apparatus 4 according to a fourth embodiment will be described with reference to FIG. 4. FIG. 4 is a cross-sectional view illustrating the substrate processing apparatus 4 according to the fourth embodiment.

The substrate processing apparatus 4 differs in main configuration from the substrate processing apparatus 1 in that the other end of the exhaust pipe 81 is connected to an exhaust pipe EP. Other configurations are the same as those of the substrate processing apparatus 1. Hereinafter, descriptions will be given focusing on the configurations different from those of the substrate processing apparatus 1.

One end of the exhaust pipe 81 is connected to the exhaust port 66c, and the other end thereof is connected to the exhaust pipe EP. With this configuration, the second space A2 may be depressurized to be in a vacuum state by a vacuum pump VP connected to the exhaust pipe EP.

With the substrate processing apparatus 4 described above, the same effects as those in the substrate processing apparatus 1 are achieved. In particular, in the substrate processing apparatus 4, one end of the exhaust pipe 81 is connected to the exhaust port 66c, and the other end of the exhaust pipe 81 is connected to the exhaust pipe EP. With this configuration, the interior of the second space A2 may be depressurized by the vacuum pump VP connected to the exhaust pipe EP. This suppresses convection in the second space A2, which improves a heat-insulating performance. Further, a difference in pressure between the first space A1 and the second space A2 becomes smaller, which reduces the strength required to the partition member 61. This reduces the thickness of the partition member 61. Thus, it is possible to decrease the heat capacity of the partition member 61 and shorten the time required to raise and lower the temperature of the heat-insulating unit 60.

In addition, the other end of the exhaust pipe 81 may be connected to an exhaust pipe other than the exhaust pipe EP. The exhaust pipe 81 may be depressurized by a vacuum pump connected to the respective exhaust pipe.

### Fifth Embodiment

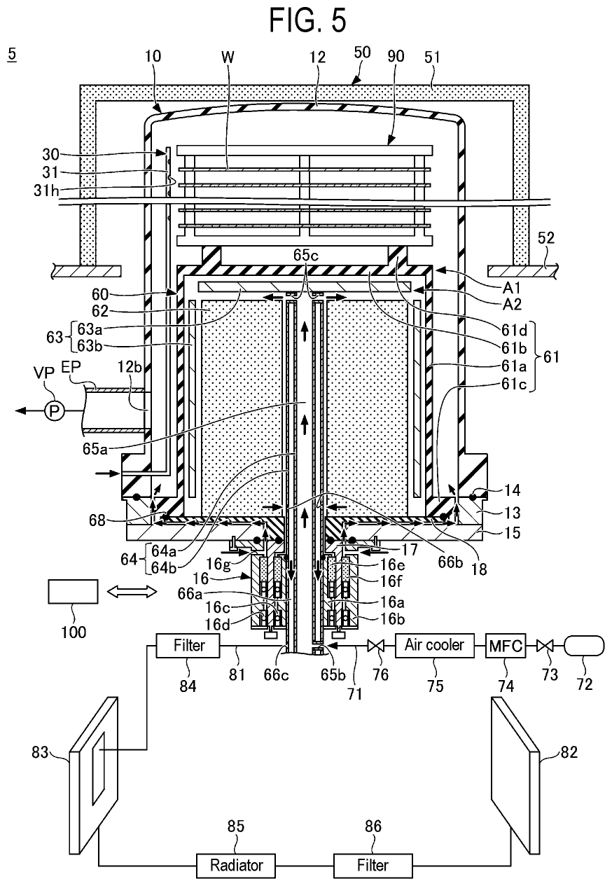

A substrate processing apparatus 5 according to a fifth embodiment will be described with reference to FIG. 5. FIG. 5 is a cross-sectional view illustrating the substrate processing apparatus 5 according to the fifth embodiment.

The substrate processing apparatus 5 differs in main configuration from the substrate processing apparatus 1 in that the processing container 10 does not have the inner tube 11 but has a single tube structure composed of the outer tube 12 and the flange member 13. Other configurations are the same as those of the substrate processing apparatus 1. Hereinafter, descriptions will be given focusing on the configurations different from those of the substrate processing apparatus 1.

The processing container 10 is a vacuum container whose interior can be depressurized. The processing container 10 accommodates substrates W therein. The processing container 10 does not have the inner tube 11, and includes the outer tube 12 and the flange member 13. The processing container 10 has the single tube structure.

With the substrate processing apparatus 5 described above, the same effects as those in the substrate processing apparatus 1 are achieved.

According to the present disclosure, it is possible to increase an internal volume of a processing container capable of accommodating a substrate holder therein.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A substrate processing apparatus comprising:
a vacuum container configured to accommodate a substrate holder configured to hold a plurality of substrates and having an opening provided in a lower end of the vacuum container;
a lid configured to open/close the opening; and
a heat-insulating unit configured to insulate a first space below the substrate holder,
wherein the heat-insulating unit includes a partition member that forms a second space partitioned from the first space, and
wherein the partition member is provided to be rotatable with respect to the lid.

2. The substrate processing apparatus of claim 1, further comprising:
a fixed shaft configured to pass through the lid while extending vertically; and
a rotary shaft provided outside the fixed shaft in a radial direction to be rotatable with respect to the fixed shaft and configured to rotate the heat-insulating unit.

3. The substrate processing apparatus of claim 2, wherein the fixed shaft includes an inner shaft and an outer shaft provided outside the inner shaft in the radial direction,
wherein a supply passage configured to supply a temperature-regulating fluid to the second space is provided inside the inner shaft, and
wherein an exhaust passage configured to exhaust the temperature-regulating fluid from the second space is provided between the inner shaft and the outer shaft.

4. The substrate processing apparatus of claim 3, wherein the supply passage is provided to communicate with the second space above the exhaust passage.

5. The substrate processing apparatus of claim 4, further comprising:
a pipe including a first end connected to the exhaust passage, and a second end connected to an exhaust portion outside the vacuum container.

6. The substrate processing apparatus of claim 5, wherein the exhaust portion is an exhaust duct configured to exhaust a loading chamber.

7. The substrate processing apparatus of claim 5, wherein the exhaust portion is a scavenger provided around the opening.

8. The substrate processing apparatus of claim 5, wherein the exhaust portion is a heater chamber provided between the vacuum container and a heater configured to heat the vacuum container from a surrounding of the vacuum container.

9. The substrate processing apparatus of claim 5, wherein the exhaust portion is an exhaust pipe configured to exhaust an interior of the vacuum container.

10. The substrate processing apparatus of claim 3, further comprising:
a pipe including a first end connected to the exhaust passage, and a second end connected to an exhaust portion outside the vacuum container.
